(19) United States
(12) Patent Application Publication
(10) Pub. No.: US 2025/0015236 A1
(43) Pub. Date: Jan. 9, 2025

(54) Phosphor Layer With Improved High-Temperature Reliability For Phosphor Converted LEDS

(71) Applicant: Lumileds LLC, San Jose, CA (US)

(72) Inventor: Rohit Modi, Hayward, CA (US)

(73) Assignee: Lumileds LLC, San Jose, CA (US)

(21) Appl. No.: 18/712,450

(22) PCT Filed: Nov. 29, 2022
(86) PCT No.: PCT/US2022/080541

§ 371 Date: May 22, 2024

Related U.S. Application Data
(60) Provisional application No. 63/284,870, filed on Dec. 1, 2021.

(51) Int. Cl. H01L 33/50; H01L 25/075; H01L 33/00

(52) U.S. Cl. CPC H01L 33/502; H01L 33/005; H01L 25/0753; H01L 2933/0041

(57) ABSTRACT

Light emitting diode (LED) devices comprise: a stack of semiconductor layers including an active region and a phosphor layer on the semiconductor layers, the phosphor layer comprising: phosphor particles, a binder material, and polydisperse inorganic filler particles. a combined solid volume percentage of the phosphor particles and the polydisperse inorganic filler particles of greater than or equal to 70% and in some embodiments, less than or equal to 90%.

### TECHNICAL FIELD

The present disclosure relates generally to light emitting diode (LED) devices and arrays. The LED devices comprise a stack of semiconductor layers including an active region and a phosphor layer. The phosphor layer comprises phosphor particles, a binder material, and polydisperse inorganic filler particles.

### BACKGROUND

Semiconductor light-emitting devices or optical power emitting devices (such as devices that emit ultraviolet (UV) or infrared (IR) optical power), including light emitting diodes, resonant cavity light emitting diodes, vertical cavity laser diodes, and edge emitting lasers, are among the most efficient light sources currently available. Due to their compact size and lower power requirements, for example, semiconductor light or optical power emitting devices (referred to herein as LEDs for simplicity) are attractive candidates for light sources, such as camera flashes, for hand-held battery-powered devices, such as cameras and cell phones. They may also be used, for example, for other applications, such as for automotive lighting, torch for video, and general illumination, such as home, shop, office and studio lighting, theater/stage lighting and architectural lighting.

High-intensity/brightness light emitting devices capable of operation across the visible spectrum include Group III-V semiconductors, particularly binary, ternary, and quaternary alloys of gallium, aluminum, indium, and nitrogen, also referred to as III-nitride materials. Typically, III-nitride light emitting devices are fabricated by epitaxially growing a stack of semiconductor layers of different compositions and dopant concentrations on a growth substrate such as a sapphire, silicon, silicon carbide, III-nitride, or other suitable substrate by metal-organic chemical vapor deposition (MOCVD), molecular beam epitaxy (MBE), or other epitaxial techniques. Sapphire is often used as the growth substrate due to its wide commercial availability and relative ease of use. The stack grown on the growth substrate typically includes one or more n-type layers doped with, for example, Si, formed over the substrate, a light emitting or active region formed over the n-type layer or layers, and one or more p-type layers doped with, for example, Mg, formed over the active region.

Phosphor converted LEDs (pc-LEDs) include a phosphor layer on an LED pump. The phosphor layer absorbs energy and converts an entering wavelength to a lower-energy wavelength. For example, the phosphor layer down-converts high energy LED light into a more desirable color spectrum. In practice, the phosphor layer composition and structure is chosen to meet desired performance criteria. Reliability is a requirement for pc-LEDs. Demand for pc-LEDs operating at high power levels has been on the rise, which in turn presents a need for pc-LED materials that to operate at high temperatures while maintaining good stability.

A conventional phosphor layer made with powder phosphors and polymer binders is prone to degradation under at high optical flux and temperature, and hence can lead to premature reliability failures of pc-LEDs. Therefore, there is a need to develop new types of phosphor layer materials/designs that can overcome their reliability shortcomings at extreme operating conditions.

### SUMMARY

Provided herein are LED devices and light sources and methods of making them.

In a first aspect, a light emitting diode (LED) device comprises: a stack of semiconductor layers including an active region; and a phosphor layer on the stack of semiconductor layers, the phosphor layer comprising: phosphor particles, a binder material, and polydisperse inorganic filler particles, and a combined solid volume percentage of the phosphor particles and the polydisperse inorganic filler particles of greater than or equal to 70%.

In another aspect, a light emitting diode (LED) device comprises: a stack of semiconductor layers including an active region; and a phosphor layer on the stack of semiconductor layers, the phosphor layer comprising: phosphor particles, a binder material, and polydisperse surface-treated inorganic filler particles, and a combined solid volume percentage of the phosphor particles and the polydisperse surface-treated inorganic filler particles of greater than or equal to 70%, the polydisperse surface-treated inorganic filler particles including a distribution of particle sizes over a range of greater than or equal to 0.1 micrometer to less than or equal to 10 micrometers.

Another aspect is a light source comprising: an array of LED devices according to any embodiment herein attached to a backplane.

A further aspect is a method of manufacturing a light emitting source comprising: positioning a wavelength converting film on a stack of semiconductor layers including an active region; and curing the wavelength converting film to form a phosphor layer on the stack of semiconductor layers and prepare a light emitting diode (LED) device, the phosphor layer comprising: phosphor particles, a binder material, and polydisperse inorganic filler particles, and a combined solid volume percentage of the phosphor particles and the polydisperse inorganic filler particles of greater than or equal to 70%.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The line drawings herein are not to scale.

FIG. 1 is a schematic view illustrating in cross-section a phosphor layer according to one or more embodiments;

FIGS. 2-8 are cross-section schematic views of various LED devices according to various embodiments;

FIG. 9 is a process flow diagram of a method of making an LED device according to one or more embodiments;

FIG. 10 shows an annotated microscopic image of an LED device processed according to one embodiment;

FIG. 11 shows an annotated microscopic image of an LED device processed according to a comparative example; and

FIG. 12 schematically illustrates an exemplary headlight illumination system comprising LEDs according to embodiments herein.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate, or on a substrate with one or more films or features or materials deposited or formed thereon.

In one or more embodiments, the “substrate” means any substrate or material surface formed on a substrate upon which film processing is performed during a fabrication process. A “growth substrate” or “LED substrate” is a substrate on which epitaxial layers including one or more active layers are prepared or grown. A “device substrate” is a substrate of a final product or device. In some embodiments, a growth substrate is removed and no additional substrate is included. In some embodiments, a growth substrate is removed and a device substrate is affixed. In some embodiments, an “LED substrate” is included in an LED pump that is affixed a device substrate. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AlN, InN and alloys), metal alloys, and other conductive materials, depending on the application. Substrates include, without limitation, light emitting diode (LED) devices, including uLED devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed are also performed on an underlayer formed on the substrate, and the term “substrate surface” is intended to include such underlayer as the context indicates. Thus for example, where a film/layer or partial film/layer has been deposited onto a substrate surface, the exposed surface of the newly deposited film/layer becomes the substrate surface.

Methods of depositing thin films include but are not limited to: sputter deposition, atomic layer deposition (ALD), chemical vapor deposition (CVD), physical vapor deposition (PVD), plasma enhanced atomic layer deposition (PEALD), plasma enhanced chemical vapor deposition (PECVD), and combinations thereof.

Reference to LED refers to a light emitting diode that emits light when current flows through it. In one or more embodiments, the LEDs herein have one or more characteristic dimensions (e.g., height, width, depth, thickness, etc. dimensions) in a range of greater than or equal to 75 micrometers to less than or equal to 300 micrometers. In one or embodiments, one or more dimensions of height, width, depth, thickness have values in a range of 100 to 300 micrometers. Reference herein to micrometers allows for variation of ±1-5%. In a preferred embodiment, one or more dimensions of height, width, depth, thickness have values of 200 micrometers ±1-5%. In some instances, the LEDs are referred to as micro-LEDs (uLEDs or μLEDs), referring to a light emitting diode having one or more characteristic dimensions (e.g., height, width, depth, thickness, etc. dimensions) on the order of micrometers or tens of micrometers. In one or embodiments, one or more dimensions of height, width, depth, thickness have values in a range of 1 to less than 75 micrometers, for example from 1 to 50 micrometers, or from 1 to 25 micrometers. Overall, in one or more embodiments, the LEDs herein may have a characteristic dimension ranging from 1 micrometers to 300 micrometers, and all values and sub-ranges therebetween.

Phosphor layers absorb energy, converting an entering wavelength to a lower-energy higher wavelength. Herein, the phosphor layers comprise phosphor particles as down-converter material. Other down-converter materials may be semiconductor nanoparticles (quantum dots), which may be used in combination with phosphor particles.

Conventional phosphor layers prepared with only powder phosphors and organic binder degrade rapidly under high temperature operating conditions of phosphor converted LEDs (pc-LEDs), and hence fail to meet long-term reliability requirements. The powder-based phosphor layers which include polydisperse inorganic filler particles presented herein have improved long-term, high-temperature reliability compared to conventional phosphor layers. In one or more embodiments, the polydisperse inorganic filler particles are surface-treated inorganic filler particles. In one or more embodiments, the polydisperse surface-treated inorganic filler particles including a distribution of particle sizes over a range of greater than or equal to 0.1 micrometer to less than or equal to 10 micrometers.

Monolithic ceramic phosphor layers are typically relied upon for higher temperature pc-LED applications, but these have limited color tunability and color quality range. The powder-based phosphor layers herein advantageously offer wider color tunability range and improved color quality while meeting high-temperature reliability requirements and presenting a lower cost option. While the LEDs herein offer many advantages, one application is high power (≥1 A/mm²) pc-LEDs with broad color tunability (CCT) range and improved color rendering quality (CRI) for illumination products. The LEDs herein are also suitable for providing low-cost powder phosphor layers for automotive front lighting products which have stringent reliability requirements.

Devices and methods herein include phosphor layers that comprise: one or more powder phosphors, polydisperse inorganic filler particles, and a polymer binder. A total volume fraction of solids (phosphors and filler combined) in the layer is typically ≥70%. This phosphor layer is typically positioned on a blue and/or near UV LED pump to yield a white pc-LED. Improvement in long-term reliability of a high-temperature phosphor layer in pc-LEDs is realized by inhibiting creation and propagation of cracks resulting from thermomechanical stresses at high temperatures by the inclusion of polydisperse inorganic filler particles.

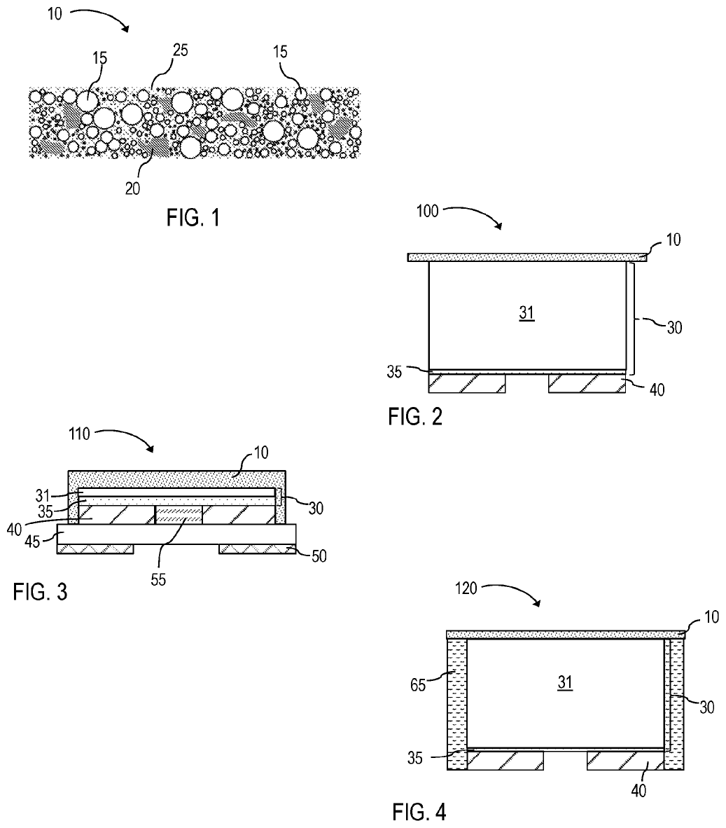

FIG. 1 is a schematic view illustrating in cross-section a phosphor layer 10 according to one or more embodiments. The phosphor layer 10 comprises polydisperse inorganic filler particles 15, phosphor particles 20, and binder (or matrix) material 25. A volume fraction in the phosphor layer of a total of the phosphor particles and the inorganic filler particles is greater than or equal to 70%. In one or more embodiments, the volume percentage in the phosphor layer of a total of the phosphor particles and the inorganic filler particles is greater than or equal to 70% and less than or equal to 90%, and all values and subranges therebetween.

In one or more embodiments, a thickness of the phosphor layer 10 is in a range of greater than or equal to 20 micrometers to less than or equal to 200 micrometers, and all values and subranges therebetween.

Reference to “polydisperse” means that the sizes of the inorganic filler particles are varied and do not center on a monomodal particle size. In one or more embodiments, the inorganic filler particles have a distribution of particle sizes that range from greater than or equal to 1 micrometer to less than or equal to 10 micrometers. In one or more embodiments, the inorganic filler particles have a D₉₀ median particle size of less than or equal to 10 micrometers.

Exemplary inorganic filler particles include but are not limited to: silica and/or aluminosilicates. Ceramic particles are also suitable as inorganic filler particles.

In one or more embodiments, the inorganic filler particles are surface-treated inorganic filler particles. Exemplary surface-treated inorganic filler particles include but are not limited to: surface-treated silica and/or surface-treated aluminosilicates. Surface-treated ceramic particles are also suitable as surface-treated inorganic filler particles.

In one or more embodiments, the surface-treated silica comprises silica and a silane coupling agent. Exemplary silane coupling agents include but are not limited to: an epoxysilane, an aminosilane, a mercaptosilane, a vinylsilane, a styrylsilane, or a methacrylsilane.

Binder materials could be organic-based or inorganic-based. Exemplary organic-based binder materials include but are not limited to silicone polymers (polysiloxane or polydialkylsiloxanes). Exemplary inorganic-based binder materials include but are not limited to dielectric material (e.g., silica).

In one embodiment a condensation cure silicone system can be used to bind phosphor particles and the inorganic filler particles. Silicone material or siloxanes can be selected for mechanical stability, low temperature cure properties (e.g. below 150-120 degrees Celsius), and ability to be catalyzed using vapor phase catalysts. In one embodiment, organosiloxane block copolymers can be used. Organopolysiloxanes containing D and T units, where the D unit are primarily bonded together to form linear blocks having 10 to 400 D units and the T units are primarily bonded to each other to form branched polymeric chains, which are referred to as “non-linear blocks” can be used.

In embodiments, the phosphor layers may be formed for use with a semiconductor structure that emits blue light. In such embodiments, the phosphor particles may include, for example, particles of a yellow emitting wavelength converting material or green and red emitting wavelength converting materials, which will produce white light when the light emitted by the respective phosphors combines with the blue light emitted by the light emitting semiconductor structure. In other embodiments, the phosphor layer may be formed for use with a semiconductor structure that emits UV light. In such embodiments, the phosphor particles may include, for example, particles of blue and yellow wavelength converting materials or particles of blue, green and red wavelength converting materials. Phosphor particles emitting other colors of light may be added to tailor the spectrum of light emitted from the LED.

In embodiments, the phosphor particles may be composed of Y₃Al₅O₁₂:Ce³⁺. The phosphor particles may be an amber to red emitting rare earth metal-activated oxonitridoalumosilicate of the general formula (Ca_{1-x-y-z}SrₓBa_{y}Mg_{z})₁₋ₙ(Al_{1-a+b}Ba)Si_{1-b}N₃·_{b}O_{b}:REₙ wherein 0≤x≤1, 0≤y≤1, 0≤z≤1, 0≤a≤1, O_{b}≤1 and 0.002≤n≤0.2, and RE may be selected from europium(II) and cerium(III).

In other embodiments, the phosphor particles may include aluminum garnet phosphors with the general formula (Lu_{1-x-y-a-b}YₓGd_{y})₃(Al_{1-z}Ga_{z})₅O₁₂: CeₐPr_{b}, wherein 0<x≤1, 0<y<1, 0≤z≤0.1, 0<a≤0.2 and 0≤b≤0.1, such as Lu₃Al₅O₁₂:Ce³⁺ and Y₃Al₅O₁₂:Ce³⁺, which emits light in the yellow-green range; and (Sr_{1-x-y}BaₓCa_{y})_{2-z}Si₅₋ₐAlₐN₈₋ₐOₐ:Eu_{z}²⁺, wherein 0≤a<5, 0≤x≤1, 0≤y≤1, and 0≤z≤1 such as Sr₂Si₅N₈:Eu²⁺, which emits light in the red range. Other green, yellow and red emitting phosphors may also be suitable, including (Sr_{1-a-b}Ca_{b}Ba_{c})SiₓN_{y}O_{z}:Euₐ 2+; (a=0.002-0.2, b=0.0-0.25, c=0.0-0.25, x=1.5-2.5, y=1.5-2.5, z=1.5-2.5) including, SrSi₂N₂O₂:Eu²⁺; (Sr₁₋ᵤ₋ᵥ₋ₓ MgᵤCaᵥ Baₓ)(Ga_{2-y-z}Al_{y}In_{z}S₄):Eu²⁺ including, for example, SrGa₂S₄:Eu²⁺; Sr₁₋ₓBaₓSiO₄:Eu²⁺; and (Ca₁₋ₓSrₓ)S:Eu²⁺ wherein 0≤x≤1 including, CaS:Eu²⁺ and SrS:Eu²⁺. Other suitable phosphors include, CaAlSiN₃:Eu²⁺,(Sr,Ca)AlSiN₃:Eu²⁺, and (Sr, Ca, Mg, Ba, Zn)(Al, B, In, Ga)(Si, Ge)N₃:Eu²⁺.

In other embodiments, the phosphor particles may also have a general formula (Sr_{1-a-b}Ca_{b}Ba_{c}Mg_{d}Znₑ)SiₓN_{y}O_{z}:Euₐ²⁺, wherein 0.002≤a≤0.2, 0.0≤b≤0.25, 0.0≤c≤0.25, 0.0≤d≤0.25, 0.0≤e≤0.25, 1.5≤x≤2.5, 1.5≤y≤2.5 and 1.5≤z≤2.5. The phosphor particles may also have a general formula of MmAaBbOoNn:Zz where an element M is one or more bivalent elements, an element A is one or more trivalent elements, an element B is one or more tetravalent elements, O is oxygen that is optional and may not be in the phosphor plate, N is nitrogen, an element Z that is an activator, n=⅔m+a+4/3b−⅔o, wherein m, a, b can all be 1 and o can be 0 and n can be 3. M is one or more elements selected from Mg (magnesium), Ca (calcium), Sr (strontium), Ba (barium) and Zn (zinc), the element A is one or more elements selected from B (boron), Al (aluminum), In (indium) and Ga (gallium), the element B is Si (silicon) and/or Ge (germanium), and the element Z is one or more elements selected from rare earth or transition metals. The element Z is at least one or more elements selected from Eu (europium), Mg (manganese), Sm (samarium) and Ce (cerium). The element A can be Al (aluminum), the element B can be Si (silicon), and the element Z can be Eu (europium).

The phosphor particles may also be an Eu²⁺ activated Sr—SiON having the formula (Sr_{1-a-b}Ca_{b}Ba_{c})SiₓN_{y}Oₓ:Euₐ, wherein a=0.002-0.2, b=0.0-0.25, c=0.0-0.25, x=1.5-2.5, y=1.5-2.5.

The phosphor particles may also be a chemically-altered Ce: YAG (Yttrium Aluminum Garnet) phosphor that is produced by doping the Ce: YAG phosphor with the trivalent ion of praseodymium (Pr). The phosphor particles may include a main fluorescent material and a supplemental fluorescent material. The main fluorescent material may be a Ce: YAG phosphor and the supplementary fluorescent material may be europium (Eu) activated strontium sulfide (SrS) phosphor (“Eu:SrS”). The main fluorescence material may also be a Ce: YAG phosphor or any other suitable yellow-emitting phosphor, and the supplementary fluorescent material may also be a mixed ternary crystalline material of calcium sulfide (CaS) and strontium sulfide (SrS) activated with europium ((CaₓSr₁₋ₓ)S:Eu²⁺). The main fluorescent material may also be a Ce:YAG phosphor or any other suitable yellow-emitting phosphor, and the supplementary fluorescent material may also be a nitrido-silicate doped with europium. The nitrido-silicate supplementary fluorescent material may have the chemical formula (Sr_{1-x-y-z} BaₓCa_{y})₂Si₅N₈:Eu_{z}²⁺ where 0≤x, y≤0.5 and 0≤z≤0.1.

In embodiments, the phosphor particles may include strontium-lithium-aluminum: europium (II) ion (SrLiAl₃N₄:Eu²⁺) class (also referred to as SLA), including MLiAl₃N₄: EU²⁺ (M=Sr, Ba, Ca, Mg). In a specific embodiment, the phosphor particles may be selected from the following group of luminescent material systems: MLiAl₃N₄:Eu (M=Sr, Ba, Ca, Mg), M₂SiO₄:Eu (M=Ba, Sr, Ca), MSe₁₋ₓSₓ:Eu (M=Sr, Ca, Mg), MSr₂S₄:Eu (M=Sr, Ca), M₂SiF₆:Mn (M=Na, K, Rb), M₂TiF₆:Mn (M=Na, K, Rb), MSiAlN₃:Eu (M=Ca, Sr), M₈Mg(SiO₄)₄Cl₂:Eu (M=Ca, Sr), M₃MgSi₂O₈:Eu (M=Sr, Ba, Ca), MSi₂O₂N₂:Eu (M=Ba, Sr, Ca), M₂Si₅₋ₓAlₓOₓN₈₋ₓ:Eu (M=Sr, Ca, Ba). However, other systems may also be of interest and may be protected by a coating. Also combinations of particles of two or more different luminescent materials may be applied, such as e.g. a green or a yellow luminescent material in combination with a red luminescent material.

In embodiments, the phosphor layer may include a blend of any of the above-described phosphors.

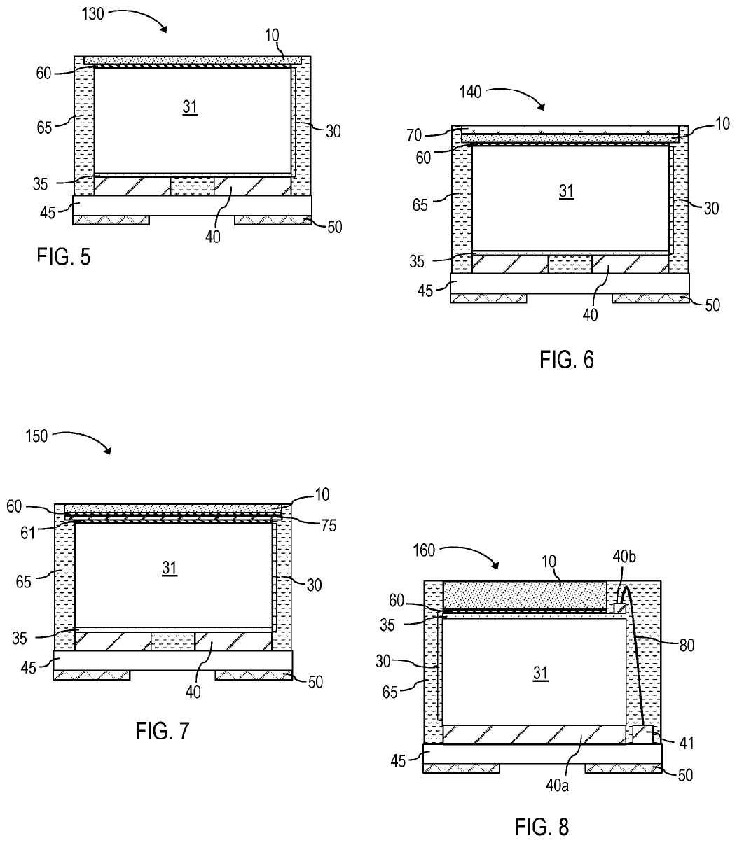

FIG. 2 is a cross-section schematic view of a LED device 100 according to an embodiment. The LED device 100 comprises an LED pump 30 comprising an LED substrate 31 and semiconductor layers including an active layer 35. The LED pump 30 is mounted on contacts 40, e.g., solder pads. The phosphor layer 10 comprising polydisperse inorganic filler particles, phosphor particles, and binder material is located on a top surface of the LED pump 30, which in this embodiment is a surface of the LED substrate 31. In other embodiments, the top surface of the LED pump 30 could be a surface of the active layer. The LED device 100 may be packaged and/or assembled singly or with other LED devices. Other features, including side reflectors, may be added to the LED device 100 for desired applications.

FIG. 3 is a cross-section schematic view of a LED device 110 according to an embodiment. The LED device 110 comprises an LED pump 30 comprising an LED substrate 31, semiconductor layers including an active layer 35, and contacts 40, e.g., solder pads. The phosphor layer 10 comprising polydisperse inorganic filler particles, phosphor particles, and binder material is located on both a top surface, which in this embodiment is a surface of the LED substrate 31, and side surfaces of the LED pump 30, which includes sides surfaces of the LED substrate 31 and the active layer 35. An underfill material 55 contacts the LED pump 30 on a bottom surface between the contacts 40. The contacts 40 affix a structure of the LED pump 30 and the phosphor layer 10 to a first surface of a device substrate 45. Additional metallization pads 50, e.g., copper (Cu) pads, are affixed to a second surface of the device substrate 45. The LED device 110 may be packaged and/or assembled singly or with other LED devices. Other features may be added to the LED device 110 for desired applications.

FIG. 4 is a cross-section schematic view of a LED device 120 according to an embodiment. The LED device 120 comprises an LED pump 30 comprising an LED substrate 31, semiconductor layers including an active layer 35, and contacts 40, e.g. solder pads. The phosphor layer 10 comprising polydisperse inorganic filler particles, phosphor particles, and binder material is located on a top surface of the LED pump 30, which in this embodiment is a surface of the LED substrate 31. A white reflector material 65 contacts the LED pump 30 on side surfaces, and on a bottom. The LED device 120 may be packaged and/or assembled singly or with other LED devices. Other features may be added to the LED device 120 for desired applications.

FIG. 5 is a cross-section schematic view of a LED device 130 according to an embodiment. The LED device 130 comprises an LED pump 30 comprising an LED substrate 31, semiconductor layers including an active layer 35, and contacts 40, e.g. solder pads. The phosphor layer 10 comprising polydisperse inorganic filler particles, phosphor particles, and binder material is affixed to a top surface of the LED pump 30, which in this embodiment is a surface of the LED substrate 31, by a layer of adhesive 60. A white reflector material 65 contacts the LED pump 30 on a bottom surface between the contacts 40, and on side surfaces of the contacts 40 and the LED pump 30. The white reflector material 65 also contacts the phosphor layer 10 on side and/or bottom surfaces. The contacts 40 affix a structure of the LED pump 30, the phosphor layer 10, the layer of adhesive 60, and the white reflector material 65 to a first surface of a device substrate 45. Additional metallization pads 50, e.g., copper (Cu) pads, are affixed to a second surface of the device substrate 45. The LED device 130 may be packaged and/or assembled singly or with other LED devices. Other features may be added to the LED device 130 for desired applications.

FIG. 6 is a cross-section schematic view of a LED device 140 according to an embodiment. The LED device 140 comprises an LED pump 30 comprising an LED substrate 31, semiconductor layers including an active layer 35, and contacts 40, e.g. solder pads. The phosphor layer 10 comprising polydisperse inorganic filler particles, phosphor particles, and binder material is affixed to a top surface of the LED pump 30, which in this embodiment is a surface of the LED substrate 31, by a layer of adhesive 60. A glass laminate 70 is on a top surface of the phosphor layer 10. A white reflector material 65 contacts the LED pump on a bottom surface between the contacts 40 and on side surfaces of the contacts 40 and the LED pump 30. The white reflector material 65 also contacts both the phosphor layer 10 and the glass laminate 65 on side and/or bottom surfaces. The contacts 40 affix a structure of the LED pump 30, the phosphor layer 10, the layer of adhesive 60, the glass laminate 70, and the white reflector material 65 to a first surface of a device substrate 45. Additional metallization pads 50, e.g., copper (Cu) pads, are affixed to a second surface of the device substrate 45. The LED device 140 may be packaged and/or assembled singly or with other LED devices. Other features may be added to the LED device 140 for desired applications.

FIG. 7 is a cross-section schematic view of a LED device 150 according to an embodiment. The LED device 150 comprises an LED pump 30 comprising an LED substrate 31, semiconductor layers including an active layer 35, and contacts 40, e.g. solder pads. A monolithic ceramic segment 75 is affixed to a top surface of the LED pump 30, which in this embodiment is a surface of the LED substrate 31, by a layer of adhesive 61. The phosphor layer 10 comprises polydisperse inorganic filler particles, phosphor particles, and binder material. The phosphor layer 10 is affixed to a top surface of the monolithic ceramic segment 75 by a layer of adhesive 60. A white reflector material 65 contacts the LED pump on a bottom surface between the contacts 40 and on side surfaces of the contacts 40 and the LED pump 30. The white reflector material 65 also contacts both the phosphor layer 10 and the monolithic ceramic segment 75 on side and/or bottom surfaces. The contacts 40 affix a structure of the LED pump 30, the phosphor layer 10, the monolithic ceramic segment 75, the layers of adhesive 60 and 61, and the white reflector material 65 to a first surface of a device substrate 45. Additional metallization pads 50, e.g., copper (Cu) pads, are affixed to a second surface of the device substrate 45. The LED device 150 may be packaged and/or assembled singly or with other LED devices. Other features may be added to the LED device 150 for desired applications.

In one or more embodiments, the monolithic ceramic segment 75 is Lumiramic™, which is a polycrystalline ceramic plate of a phosphor material. A Lumiramic plate suitable for the monolithic ceramic segment may be made from a Ce(III) doped garnet material ((M_{i-x-y}^{I}M^{II}ₓ Mᵢ^{IIy})₃(Ali__{z}M^{Iv}_{z})₅0 i₂ with M¹=(Y, Lu); M^{II}=(Gd, La, Yb); M^{II}ᵢ=(Tb, Pr, Ce, Er, Nd, Eu) and M^{IV}=(Gd, Sc) with 0<x<1; 0<y≤0, 1 und 0<z<1) or from Ce(III) and/or Eu(II) doped nitridosilicate (M₂Si₅N₈) and oxonitridosilicate materials (MSi₂O₂N₂) (M=alkaline earth). In one or more embodiments, a combination of the phosphor layer 10 and the monolithic ceramic segment 75 could be useful for some applications where a wider color gamut is required, which cannot be achieved with only a Lumiramic plate for high power, high temperature reliability. Advantageously, such a combination could further improve the reliability while extending the color gamut.

FIG. 8 is a cross-section schematic view of a LED device 160 according to an embodiment. The LED device 160 is representative of a vertical thin film (VTF) die with a wire bond. The LED device 160 comprises an LED pump 30 comprising an LED substrate 31, semiconductor layers including an active layer 35, and contacts 40a and 40b. A further contact 41 is in contact with the substrate 45. The phosphor layer 10 comprising polydisperse inorganic filler particles, phosphor particles, and binder material is affixed to a top surface of the LED pump 30, which in this embodiment is a surface of the active layer 35, by a layer of adhesive 60. A white reflector material 65 contacts the LED pump 30 on side surfaces of the contacts 40a, 40b, and 41 and the LED pump 30. The white reflector material 65 also contacts the phosphor layer 10 on side and/or bottom surfaces. The contact 40a affixes a structure of the LED pump 30, the phosphor layer 10, the layer of adhesive 60, and the white reflector material 65 to a first surface of a device substrate 45. The contact 40b is connected to the contact 41 by a wire bond 80. Additional metallization pads 50, e.g., copper (Cu) pads, are affixed to a second surface of the device substrate 45. The LED device 160 may be packaged and/or assembled singly or with other LED devices. Other features may be added to the LED device 130 for desired applications.

The LED pumps can be formed from an epitaxially grown or deposited semiconductor layers. A semiconductor n-layer can be formed on a growth substrate. A semiconductor p-layer can then be sequentially grown or deposited on the n-layer, forming an active region at the junction between layers. Semiconductor materials capable of forming high-brightness light emitting devices can include, but are not limited to, Group III-V semiconductors, particularly binary, ternary, and quaternary alloys of gallium, aluminum, indium, and nitrogen, also referred to as III-nitride materials. The semiconductor layers may be formed from III-V semiconductors including, but not limited to, AlN, AlP, AlAs, AlSb, GaN, GaP, GaAs, GaSb, InN, InP, InAs, InSb, II-VI semiconductors including, but not limited to, ZnS, ZnSe, CdSe, CdTe, group IV semiconductors including, but not limited to Ge, Si, SiC, and mixtures or alloys thereof. These example semiconductors have indices of refraction ranging from about 2.4 to about 4.1 at the typical emission wavelengths of LEDs in which they are present.

Substrates, e.g., LED substrates and/or device substrates, may be formed of any suitable material, including but not limited to sapphire and/or silicon carbide. In one or more embodiments, the LED substrate comprises silicon carbide, sapphire, gallium nitrate, or silicon. In one or more embodiments, the device substrate is a ceramic substrate.

Direction, beam width, and beam shape of light emitted from each LED can be modified by optical elements. The optical elements a single optical element or a multiple optic elements. Optical elements can include converging or diverging lenses, aspherical lens, Fresnel lens, or graded index lens, for example. Other optical elements such as mirrors, beam diffusers, filters, masks, apertures, collimators, or light waveguides are also included. Optical elements can be positioned at a distance from the LEDs that allows receipt and redirection of light from multiple LEDs. Alternatively, optical elements can be set atop each LED to individually guide, focus, or defocus emitted LED light. Optical elements can be directly attached to the LEDs, attached to LEDs via a transparent interposer or plate, or held at a fixed distance from LEDs by surrounding substrate attachments.

In a first aspect, provided are a light emitting diode (LED) devices comprising: a stack of semiconductor layers including an active region; and a phosphor layer on the stack of semiconductor layers, the phosphor layer comprising: phosphor particles, a binder material, and polydisperse inorganic filler particles, and a combined solid volume percentage of the phosphor particles and the polydisperse inorganic filler particles of greater than or equal to 70%.

In another aspect, a light emitting diode (LED) device comprises: a stack of semiconductor layers including an active region; and a phosphor layer on the stack of semiconductor layers, the phosphor layer comprising: phosphor particles, a binder material, and polydisperse surface-treated inorganic filler particles, and a combined solid volume percentage of the phosphor particles and the polydisperse surface-treated inorganic filler particles of greater than or equal to 70%, the polydisperse surface-treated inorganic filler particles including a distribution of particle sizes over a range of greater than or equal to 0.1 micrometer to less than or equal to 10 micrometers.

In one or more embodiments, the LED device comprising the phosphor layer exhibits a time-to-failure of at least four times a time-to-failure of a comparative LED device comprising a comparative phosphor layer in the absence of the polydisperse inorganic filler particles, when the LED device and the comparative the LED device are tested under an accelerated high-temperature operating life (HTOL) test under conditions of: 2 amp/mm² current density and 180° C. junction temperature. In one or more embodiments, the LED device comprising the phosphor layer exhibits a time-to-failure of at least four times a time-to-failure of a comparative LED device comprising a comparative phosphor layer in the absence of the polydisperse surface-treated inorganic filler particles, when the LED device and the comparative the LED device are tested under an accelerated high-temperature operating life (HTOL) test under conditions of: 2 amp/mm² current density and 180° C. junction temperature. Comparative phosphor layers typically utilize monodisperse inorganic filter particles. In one or more embodiments, the LED device comprising the phosphor layer exhibits a time-to-failure of at least four times a time-to-failure of a comparative LED device comprising a comparative phosphor layer in the presence of monodisperse inorganic filler particles, when the LED device and the comparative the LED device are tested under an accelerated high-temperature operating life (HTOL) test under conditions of: 2 amp/mm² current density and 180° C. junction temperature.

In another aspect, a light source comprises: an array of LED devices according to any LED devices herein attached to a backplane.

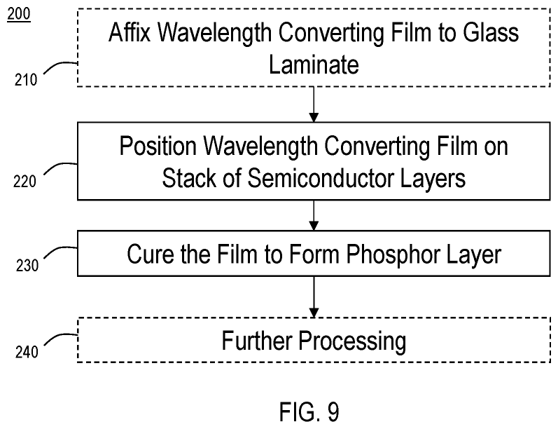

FIG. 9 is a process flow diagram of a method of making an LED device 200 according to one or more embodiments. At operation 220, a wavelength converting film is positioned on a stack of semiconductor layers including an active region to form a structure. In some embodiments, the wavelength converting film is provided on a temporary tape. The wavelength converting film may be a molding compound formed from a binder or matrix material, such as silicone, that is highly loaded with phosphor particles as well as polydisperse inorganic filler particles. In one or more embodiments, the inorganic filler particles are surface-treated inorganic filler particles, such as surface-treated silica (SiO₂). A concentration of solids (the phosphor and filler particles) in the molding compound may be between 70 and 90% by volume. The temporary tape may be any suitable sawing tape. The wavelength converting film may be sawed or otherwise separated into individual wavelength converting structures.

At operation 230, the structure of operation 220 is cured such that the wavelength converting film forms a phosphor layer. In one or more embodiments, the structures are cured at conditions of, for example, a temperature in a range of 150° C.-180° C. over a duration of four to eight hours. The wavelength converting film composition is chosen to include the following ingredients: phosphor particles, a binder material, and polydisperse inorganic filler particles. The phosphor layer upon processing or curing comprises: the phosphor particles, the binder material, and the polydisperse inorganic filler particles, wherein a combined solid volume percentage of the phosphor particles and the polydisperse inorganic filler particles of greater than or equal to 70%.

At operation 210, optionally, the wavelength converting film is affixed to a glass laminate.

At operation 240, optional further processing is performed. In one or more embodiments, further processing including formation of a passivation layer around a portion or the entirety of the array. In one or more embodiments, contacts are coupled to the structure, either directly or via another structure such as a submount, for electrical connection to a circuit board or other substrate or device. In embodiments, the contacts may be electrically insulated from one another by a gap, which may be filled with a dielectric material.

In summary, methods herein comprise: of manufacturing a light emitting source comprising: positioning a wavelength converting film on a stack of semiconductor layers including an active region; and curing the wavelength converting film to form a phosphor layer on the stack of semiconductor layers and prepare a light emitting diode (LED) device, the phosphor layer comprising: phosphor particles, a binder material, and polydisperse inorganic filler particles, and a combined solid volume percentage of the phosphor particles and the polydisperse inorganic filler particles of greater than or equal to 70%. Optionally, a first surface of the wavelength converting film to a glass laminate prior to positioning a second surface of the wavelength converting film on a stack of semiconductor layers. In one or more embodiments, the wavelength converting film is attached to the stack of semiconductor layers with an adhesive. In one or more embodiments, the stack of semiconductor layers to a substrate

### Applications

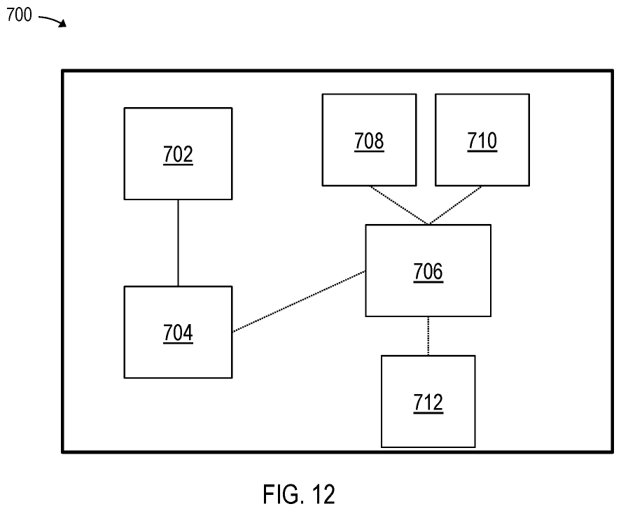

FIG. 12 schematically illustrates an exemplary headlight illumination system 700 utilizing LEDs disclosed herein. The headlight illumination system 700 comprises an LED illumination array and lens system 702 in electrical communication with an LED driver 704. The headlight illumination system 700 also comprises a controller 706, such as a microprocessor. The controller 706 is coupled to the LED driver 704. The controller 706 may also be coupled to one or more auxiliary components 708 and sensors 710 associated with the headlights, and operate in accordance with instructions and profiles stored in memory 712.

Sensors 710 may include, for example, positional sensors (e.g., a gyroscope and/or accelerometer) and/or other sensors that may be used to determine the position, speed, and orientation of system 700. The signals from the sensors 710 may be supplied to the controller 706 to be used to determine the appropriate course of action of the controller 706 (e.g., which LEDs are currently illuminating a target and which LEDs will be illuminating the target a predetermined amount of time later).

In operation, illumination from some or all of the pixels of the LED array in 702 may be adjusted—deactivated, operated at full intensity, or operated at an intermediate intensity. As noted above, beam focus or steering of light emitted by the LED array in 702 can be performed electronically by activating one or more subsets of the pixels, to permit dynamic adjustment of the beam shape without moving optics or changing the focus of the lens in the lighting apparatus.

LED illumination arrays and lens systems such as described herein may support various other beam steering or other applications that benefit from fine-grained intensity, spatial, and temporal control of light distribution. These applications may include, but are not limited to, precise spatial patterning of emitted light from pixel blocks or individual pixels. Depending on the application, emitted light may be spectrally distinct, adaptive over time, and/or environmentally responsive. The light emitting pixel arrays may provide pre-programmed light distribution in various intensity, spatial, or temporal patterns. Associated optics may be distinct at a pixel, pixel block, or device level. An example light emitting pixel array may include a device having a commonly controlled central block of high intensity pixels with an associated common optic, whereas edge pixels may have individual optics. In addition to flashlights, common applications supported by light emitting pixel arrays include video lighting, camera flashes, architectural and area illumination, and street lighting.

In some embodiments, each LED device in a light source array can be separately controlled, while in other embodiments groups of LEDs can be controlled as a block. In still other embodiments, both single LEDs and groups of LEDs can be controlled. To reduce overall data management requirements, control can be limited to on/off functionality or switching between relatively few light intensity levels. In other embodiments, continuous changes in lighting intensity are supported. Both individual and group level control of light intensity is contemplated. In one embodiment, overlapping or dynamically selected zones of control are also possible, with for example, overlapping groups of light emitters in the array being separately controllable despite having common LEDs depending on lighting requirements. In one embodiment, intensity can be separately controlled and adjusted by setting appropriate ramp times and pulse width for each LED using a pulse width modulation. This allows staging of LED activation to reduce power fluctuations, and to provide superior luminous intensity control.

Programmable light emitting arrays such as disclosed herein may also support a wide range of applications that benefit from fine-grained intensity, spatial, and temporal control of light distribution. This may include, but is not limited to, precise spatial patterning of emitted light from blocks or individual LEDs. Depending on the application, emitted light may be spectrally distinct, adaptive over time, and/or environmentally responsive. In some embodiments, the light emitting arrays may provide pre-programmed light distribution in various intensity, spatial, or temporal patterns. The emitted light may be based at least in part on received sensor data and may be used for optical wireless communications. Associated optics may be distinct at single or multiple LED level. An example light emitting array may include a device having a commonly controlled central block of high intensity LEDS with an associated common optic, whereas edge positioned LEDs may have individual optics. Common applications supported by light emitting LED arrays include camera or video lighting, architectural and area illumination, and street lighting.

Programmable light emitting arrays may be used to selectively and adaptively illuminate buildings or areas for improved visual display or to reduce lighting costs. In addition, light emitting arrays may be used to project media facades for decorative motion or video effects. In conjunction with tracking sensors and/or cameras, selective illumination of areas around pedestrians may be possible. Spectrally distinct LEDs may be used to adjust the color temperature of lighting, as well as support wavelength specific horticultural illumination.

Street lighting is an important application that may greatly benefit from use of programmable light emitting arrays. A single type of light emitting array may be used to mimic various street light types, allowing, for example, switching between a Type I linear street light and a Type IV semicircular street light by appropriate activation or deactivation of selected LEDs. In addition, street lighting costs may be lowered by adjusting light beam intensity or distribution according to environmental conditions or time of use. For example, light intensity and area of distribution may be reduced when pedestrians are not present. If LEDs are spectrally distinct, the color temperature of the light may be adjusted according to respective daylight, twilight, or night conditions.

Programmable light emitting LEDs are also well suited for supporting applications requiring direct or projected displays. For example, automotive headlights requiring calibration, or warning, emergency, or informational signs may all be displayed or projected using light emitting arrays. This allows, for example, modifying directionality of light output from a automotive headlight. If a light emitting array is composed of a large number of LEDs or includes a suitable dynamic light mask, textual or numerical information may be presented with user guided placement. Directional arrows or similar indicators may also be provided.

### EXAMPLES

A series of phosphor-converted light emitting diode (pc-LED) dies were prepared using a series of phosphor layer compositions according to Table 1.

TABLE 1
Phosphor Layer Compositions.

| | | | SOLIDS | | |
|---|---|---|---|---|---|
| | | | TOTAL | | |
| | CARRIER | | of phosphor | | |
| | TOTAL of binder | | particles & | filler | Layer/Glass |
| | material | | filler particles | particles | Assembly |
| # | Description | Vol. % | Vol. % | Description | Description |
| Cell-E | Silicone A | 30 | 70 | Surface-treated | No glue |
| | RI 1.49 | | | SILICA | |
| | | | | Particle size | |
| | | | | (diameter) includes | |
| | | | | distribution from 0.1 | |
| | | | | μm to 10 μm | |
| Cell-D | Silicone A | 30 | 70 | Same as Cell-E | Glue |
| | RI 1.49 | | | | |
| Cell-A | Silicone A | 70 | 30 | SILICA - no | No glue |
| | RI 1.49 | | | surface treatment | |
| | | | | Particle size | |
| | | | | (diameter) includes | |
| | | | | distribution from 12 | |
| | | | | μm to 15 μm | |
| | | | | D₉₀ < 24 μm | |
| Cell-B | Silicone A | 70 | 30 | Same as Cell-A | Glue |
| | RI 1.49 | | | | |
| Cell-F | Silicone B | 70 | 30 | Same as Cell-A | No glue |
| | RI 1.47 | | | | |
| Cell-G | Dimethyl | 70 | 30 | Same as Cell-A | No glue |
| | silicone | | | | |
| | RI 1.41 | | | | |
| Cell-P | Silicone A | 30 | 70 | Same as Cell-A | Glue |
| | RI 1.49 | | | | |

In these examples, phosphor layer films were laminated onto a glass and cured to form laminated glasses including the phosphor layers. LED pumps (including multiple semi-conductor layers and an active region) were soldered onto a sapphire substrate to form an LED die. The laminated glasses were then inverted and assembled onto the LED die to form the LED devices (also referred to as pc-LED).

Table 2 provides pass-fail results of accelerated high-temperature operating life (HTOL) tests after intervals of time. Color shift (dy) was used as a metric for the assessing relative stability of a pc-LED during a reliability test. A sample passed (denoted as “P”) when the color shift (dy) was between 0.01 and −0.01, otherwise the sample failed (denoted as “F”). Test conditions varied current density (amp/mm²) and junction temperature (Tj) over stress time (hours).

Cells D and E were white pc-LED with the inventive phosphor layer, suitable for high-temperature reliability, whereas the other cells (A, B, F, G, P) were comparative white pc-LEDs with different embodiments with comparative phosphor layers.

TABLE 2
HTOL test results.
CONDITIONS

| | Current density (amp/mm²) | | | | | | | | | | | | | | |
|---|---|---|---|---|---|---|---|---|---|---|---|---|---|---|---|
| | 1 | | | | 1.25 | | | | 1.5 | | | 2.0 | | | |
| | Junction temperature (Tj) (° C.) | | | | | | | | | | | | | | |
| | 150 | | | | 150 | | | | 150 | | | 180 | | | |
| | Stress time (hours) | | | | | | | | | | | | | | |
| | 500 | 1000 | 1500 | 2000 | 500 | 1000 | 1500 | 2000 | 500 | 1000 | 1500 | 168 | 200 | 500 | 1000 |
| Cell-E | P | P | P | P | P | P | P | P | P | P | P | P | P | P | F |
| Cell-D | P | P | P | P | P | P | P | P | P | P | P | P | P | P | F |
| Cell-A | P | P | P | F | P | P | F | F | P | P | F | F | F | F | F |
| Cell-B | P | P | P | F | P | P | F | F | P | P | F | F | F | F | F |
| Cell-F | P | P | P | P | P | P | F | F | F | F | F | F* | F | F | F |
| Cell-G | P | P | P | P | P | P | P | P | P | P | P | P | F | F | F |
| Cell-P | P | P | P | F | — | — | — | — | — | — | — | F** | F | F | F |

*failure occurred at 24 hrs
**failure occurred at 72 hrs

Cells D and E show at least 4× improvement in time-to-failure compared to cells with conventional phosphor layers at a highly accelerated stress condition of 2 A/mm² current density and 180° C. junction temperature (Tj).

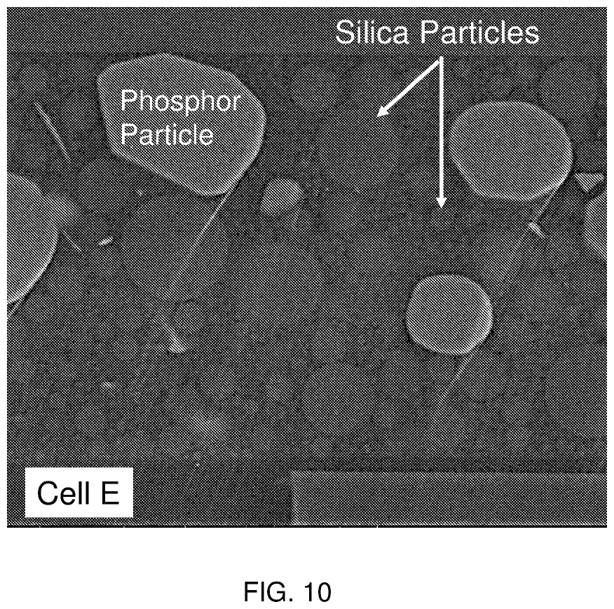

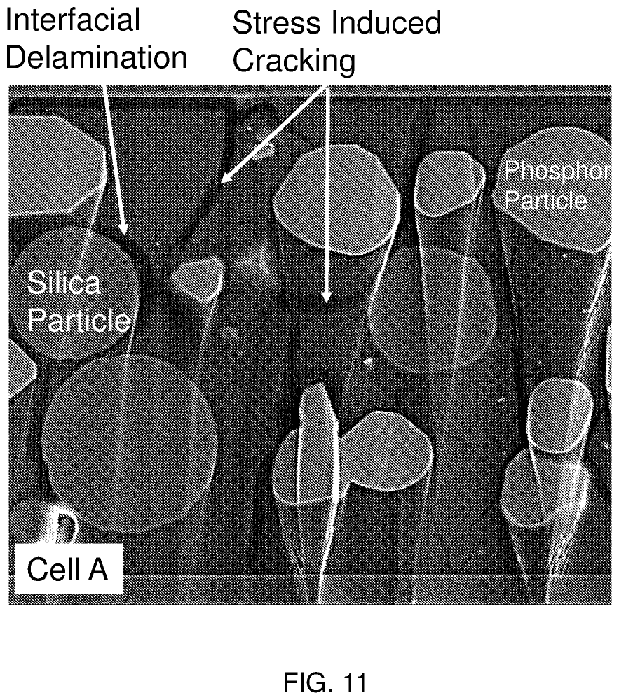

FIGS. 10-11 provide cross-sectional images of the high-temperature phosphor layer and the conventional phosphor layer, respectively, in a blue pumped pc-LED structure according to FIG. 6 after 1000 hrs of the HTOL test (2 A/mm², 180° C. Tj stress). FIG. 10 shows an annotated microscopic image of Cell E with the high-temperature phosphor layer showing an absence of cracking after 1000 hrs of the HTOL test. FIG. 11 shows an annotated microscopic image of Cell A with conventional phosphor layer showing cracking after 1000 hrs of the HTOL test. Massive stress induced cracks are seen in the conventional layer of FIG. 11, whereas the high-temperature phosphor layer shows no cracks in FIG. 10.

Without intending to be bound by theory, the improved crack resistance of the high-temperature phosphor layer can be attributed to the following factors:
lower coefficient of thermal expansion (CTE) due to high solid content, and hence lower thermomechanical stresses;
lower layer temperature due to higher thermal conductivity, and hence lower rate of binder degradation; and
uniform packing of solids, reduced defects, and crack propagation mitigation due to surface treatment and polydispersity of filler.

### EMBODIMENTS

Various embodiments are listed below. It will be understood that the embodiments listed below may be combined with all aspects and other embodiments in accordance with the scope of the invention.

Embodiment (a) A light emitting diode (LED) device comprising: a stack of semiconductor layers including an active region; and a phosphor layer on the stack of semiconductor layers, the phosphor layer comprising: phosphor particles, a binder material, and polydisperse inorganic filler particles, and a combined solid volume percentage of the phosphor particles and the polydisperse inorganic filler particles of greater than or equal to 70%.

Embodiment (b) The LED device of embodiment (a), wherein the LED device comprising the phosphor layer exhibits a time-to-failure of at least four times greater than a time-to-failure of a comparative LED device comprising a comparative phosphor layer in the absence of the polydisperse inorganic filler particles, when the LED device and the comparative the LED device are tested under an accelerated high-temperature operating life (HTOL) test under conditions of: 2 amp/mm² current density and 180° C. junction temperature.

Embodiment (c) The LED device of any of embodiments (a) to (b), wherein the solid volume percentage in the phosphor layer of the phosphor particles and the polydisperse inorganic filler particles is less than or equal to 90%.

Embodiment (d) The LED device of any of embodiments (a) to (c), wherein the polydisperse inorganic filler particles includes a distribution of particle sizes over a range of greater than or equal to 0.1 micrometer to less than or equal to 10 micrometers.

Embodiment (e) The LED device of any of embodiments (a) to (d), wherein a D₉₀ median particle size of the polydisperse inorganic filler particles is less than or equal to 10 micrometers.

Embodiment (f) The LED device of any of embodiments (a) to (e), wherein the inorganic filler particles comprise: silica and/or aluminosilicates.

Embodiment (g) The LED device of embodiment (f), wherein the inorganic filler particles are inorganic filler particles

Embodiment (h) The LED device of embodiment (g), wherein the surface-treated inorganic filter particles comprise silica and a silane coupling agent.

Embodiment (i) The LED device of embodiment (h), wherein the silane coupling agent comprises an epoxysilane, an aminosilane, a mercaptosilane, a vinylsilane, a styrylsilane, or a methacrylsilane.

Embodiment (j) The LED device of any of embodiments (a) to (i), wherein the binder material comprises a silicone polymer.

Embodiment (k) The LED device of any of embodiments (a) to (j), wherein the binder material comprises a dielectric material.

Embodiment (l) The LED device of any of embodiments (a) to (k) having at least one characteristic dimension of greater than or equal to 1 micrometer less than or equal to 300 micrometers, the characteristic dimension being selected from the group consisting of: height, width, depth, thickness, and combinations thereof.

Embodiment (m) The LED device of any of embodiments (a) to (1) further comprising a substrate to which the stack of semiconductor layers is affixed.

Embodiment (n) The LED device any of embodiments (a) to (1) further comprising a monolithic ceramic segment affixed to the stack of semiconductor layers between the stack of semiconductor layers and the phosphor layer.

Embodiment (o) A light emitting diode (LED) device comprising: a stack of semiconductor layers including an active region; and a phosphor layer on the stack of semiconductor layers, the phosphor layer comprising: phosphor particles, a binder material, and polydisperse surface-treated inorganic filler particles, and a combined solid volume percentage of the phosphor particles and the polydisperse inorganic filler particles of greater than or equal to 70%; the polydisperse surface-treated inorganic filler particles including a distribution of particle sizes over a range of greater than or equal to 0.1 micrometer to less than or equal to 10 micrometers.

Embodiment (p) The LED device of embodiment (o), wherein the LED device comprising the phosphor layer exhibits a time-to-failure of at least four times greater than a time-to-failure of a comparative LED device comprising a comparative phosphor layer in the absence of the polydisperse surface-treated inorganic filler particles, when the LED device and the comparative the LED device are tested under an accelerated high-temperature operating life (HTOL) test under conditions of: 2 amp/mm² current density and 180° C. junction temperature.

Embodiment (q) The LED device of any of embodiments (o) to (p), wherein the solid volume percentage in the phosphor layer of the phosphor particles and the polydisperse surface-treated inorganic filler particles is less than or equal to 90%.

Embodiment (r) The LED device of any of embodiments (o) to (q), wherein a D₉₀ median particle size of the polydisperse surface-treated inorganic filler particles is less than or equal to 10 micrometers.

Embodiment (s) The LED device of any of embodiments (o) to (r), wherein the surface-treated inorganic filler particles comprise: surface-treated silica and/or surface-treated aluminosilicates.

Embodiment (t) The LED device of any of embodiments (o) to (s), wherein the surface-treated silica comprises silica and a silane coupling agent.

Embodiment (u) The LED device of embodiment (t), wherein the silane coupling agent comprises an epoxysilane, an aminosilane, a mercaptosilane, a vinylsilane, a styrylsilane, or a methacrylsilane.

Embodiment (v) The LED device of any of embodiments (o) to (u), wherein the binder material comprises a silicone polymer, and/or the binder material comprises a dielectric material.

Embodiment (w) The LED device of any of embodiments (o) to (v) having at least one characteristic dimension of greater than or equal to 1 micrometer less than or equal to 300 micrometers, the characteristic dimension being selected from the group consisting of: height, width, depth, thickness, and combinations thereof.

Embodiment (x) The LED device of any of embodiments (o) to (w) further comprising a substrate to which the stack of semiconductor layers is affixed.

Embodiment (y) The LED device of any of embodiments (o) to (x) further comprising a monolithic ceramic segment affixed to the stack of semiconductor layers between the stack of semiconductor layers and the phosphor layer.

Embodiment (z) A light source comprising: an array of LED devices according to any of embodiments (a) to (y) attached to a backplane.

Embodiment (aa) The light source of embodiment (z), wherein each LED device is individually addressable.

Embodiment (bb) A method of manufacturing a light emitting source comprising: positioning a wavelength converting film on a stack of semiconductor layers including an active region; and curing the wavelength converting film to form a phosphor layer on the stack of semiconductor layers and prepare a light emitting diode (LED) device, the phosphor layer comprising: phosphor particles, a binder material, and polydisperse inorganic filler particles, and a combined solid volume percentage of the phosphor particles and the polydisperse surface-treated inorganic filler particles of greater than or equal to 70%.

Embodiment (cc) The method of embodiment (bb) further comprising attaching the wavelength converting film to the stack of semiconductor layers with an adhesive.

Embodiment (dd) The method of any of embodiments (bb) to (cc) further comprising affixing the stack of semiconductor layers to a substrate.

Embodiment (ee) The method of any of embodiments (bb) to (dd) further comprising attaching a first surface of the wavelength converting film to a glass laminate prior to positioning a second surface of the wavelength converting film on a stack of semiconductor layers.

Embodiment (ff) The method of any of embodiments (bb) to (ee) further comprising assembling an array of the LED devices on a backplane to form an LED array.

Embodiment (gg) The method of any of embodiments (bb) to (ff), wherein the solid volume percentage in the phosphor layer of the phosphor particles and the polydisperse inorganic filler particles is less than or equal to 90%; and/or the polydisperse surface-treated inorganic filler particles includes a distribution of particle sizes over a range of greater than or equal to 0.1 micrometer to less than or equal to 10 micrometers.

Embodiment (hh) The method any of embodiments (bb) to (gg) further comprising affixing a monolithic ceramic segment to the stack of semiconductor layers between the stack of semiconductor layers and the phosphor layer.

Embodiment (ii) The method of any of embodiments (bb) to (hh), wherein the inorganic filler particles are surface-treated inorganic filler particles.

Embodiment (j) The method of any of embodiments (bb) to (ii), wherein the surface-treated inorganic filler particles comprise: surface-treated silica and/or surface-treated aluminosilicates.

Embodiment (kk) The method of any of embodiments (bb) to (j), wherein the surface-treated silica comprises silica and a silane coupling agent.

Embodiment (11) The method of embodiment (kk), wherein the silane coupling agent comprises an epoxysilane, an aminosilane, a mercaptosilane, a vinylsilane, a styrylsilane, or a methacrylsilane.

Embodiment (mm) The method of any of embodiments (bb) to (11), wherein the binder material comprises a silicone polymer, and/or the binder material comprises a dielectric material.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims. It is also understood that other embodiments of this invention may be practiced in the absence of an element/step not specifically disclosed herein.

What is claimed is:

1. A light emitting diode (LED) device comprising:
a stack of semiconductor layers including an active region; and
a phosphor layer on the stack of semiconductor layers, the phosphor layer comprising: phosphor particles, a binder material, and polydisperse inorganic filler particles, and a combined solid volume percentage of the phosphor particles and the polydisperse inorganic filler particles of greater than or equal to 70%.

2. The LED device of claim 1, wherein the LED device comprising the phosphor layer exhibits a time-to-failure of at least four times greater than a time-to-failure of a comparative LED device comprising a comparative phosphor layer in the absence of the polydisperse inorganic filler particles, when the LED device and the comparative the LED device are tested under an accelerated high-temperature operating life (HTOL) test under conditions of: 2 amp/mm² current density and 180° C. junction temperature.

3. The LED device of claim 1, wherein the solid volume percentage in the phosphor layer of the phosphor particles and the polydisperse inorganic filler particles is less than or equal to 90%.

4. The LED device of claim 1, wherein the polydisperse inorganic filler particles includes a distribution of particle sizes over a range of greater than or equal to 0.1 micrometer to less than or equal to 10 micrometers.

5. The LED device of claim 1, wherein a D₉₀ median particle size of the polydisperse inorganic filler particles is less than or equal to 10 micrometers.

6. The LED device of claim 1, wherein the inorganic filler particles comprise: silica and/or aluminosilicates.

7. The LED device of claim 6, wherein the inorganic filler particles are surface-treated inorganic filler particles.

8. The LED device of claim 1, wherein the binder material comprises a silicone polymer and/or the binder material comprises a dielectric material.

9. The LED device of claim 1 having at least one characteristic dimension of greater than or equal to 1 micrometer less than or equal to 300 micrometers, the characteristic dimension being selected from the group consisting of: height, width, depth, thickness, and combinations thereof.

10. The LED device of claim 1 further comprising a substrate to which the stack of semiconductor layers is affixed.

11. A light emitting diode (LED) device comprising:
a stack of semiconductor layers including an active region;
a phosphor layer on the stack of semiconductor layers, the phosphor layer comprising: phosphor particles, a binder material, and polydisperse surface-treated inorganic filler particles, and a combined solid volume percentage of the phosphor particles and the polydisperse inorganic filler particles of greater than or equal to 70%; and
the polydisperse surface-treated inorganic filler particles including a distribution of particle sizes over a range of greater than or equal to 0.1 micrometer to less than or equal to 10 micrometers.

12. The LED device of claim 11, wherein a D₉₀ median particle size of the polydisperse surface-treated inorganic filler particles is less than or equal to 10 micrometers.

13. The LED device of claim 11, wherein the surface-treated inorganic filler particles comprise: surface-treated silica and/or surface-treated aluminosilicates.

14. The LED device of claim 13, wherein the surface-treated silica comprises silica and a silane coupling agent.

15. The LED device of claim 14, wherein the silane coupling agent comprises an epoxysilane, an aminosilane, a mercaptosilane, a vinylsilane, a styrylsilane, or a methacrylsilane.

16. The LED device of claim 11, wherein the binder material comprises a silicone polymer, and/or the binder material comprises a dielectric material.

17. The LED device of claim 11 having at least one characteristic dimension of greater than or equal to 1 micrometer less than or equal to 300 micrometers, the characteristic dimension being selected from the group consisting of: height, width, depth, thickness, and combinations thereof.

18. A light source comprising: an array of LED devices according to claim 1 attached to a backplane.

19. The light source of claim 18, wherein each LED device is individually addressable.

20. A method of manufacturing a light emitting source comprising:
positioning a wavelength converting film on a stack of semiconductor layers including an active region; and
curing the wavelength converting film to form a phosphor layer on the stack of semiconductor layers and prepare a light emitting diode (LED) device, the phosphor layer comprising: phosphor particles, a binder material, and polydisperse inorganic filler particles, and a combined solid volume percentage of the phosphor particles and the polydisperse surface-treated inorganic filler particles of greater than or equal to 70%.
